(19) United States
(12) Patent Application Publication
(10) Pub. No.: US 2006/0246666 A1
(43) Pub. Date: Nov. 2, 2006

(54) Method of fabricating flash memory with u-shape floating gate

(76) Inventors: Jeong-nam Han, Seoul (KR); Dong-chan Kim, Seoul (KR); Chang-jin Kang, Seongnam-si (KR); Kyeong-koo Chi, Seoul (KR); Woo-gwan Shim, Yongin-si (KR); Hyo-san Lee, Suwon-si (KR); Chang-ki Hong, Seongnam-si (KR); Sang-jun Choi, Seoul (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/410,837

(22) Filed: Apr. 26, 2006

(30) Foreign Application Priority Data
Apr. 27, 2005 (KR) 10-2005-0034914

(51) Int. Cl. H01L 21/336

(52) U.S. Cl. 438/263; 438/264

(57) ABSTRACT

A method of fabricating a flash memory having a U-shape floating gate is provided. The method includes forming adjacent isolation layers separated by a gap and forming a tunnel oxide layer in the gap. After a conductive layer is formed on the tunnel oxide layer to a thickness not to fill the gap, a polishing sacrificial layer is formed on the conductive layer. The sacrificial layer and the conductive layer on the isolation layers are removed, thereby forming a U-shape floating gate self-aligned in the gap, and concurrently forming a sacrificial layer pattern within an inner portion of the floating gate. Selected isolation layers are then recessed to expose sidewalls of the floating gate. The sacrificial layer pattern is then removed from the floating gate to expose an upper surface of the floating gate.

### BACKGROUND OF THE INVENTION

1. Field of the Invention

Embodiments of the invention relate to a method of fabricating a flash memory device. More particularly, embodiments of the invention relate to a method of fabricating a flash memory device having a U-shape floating gate.

This application claims the benefit of Korean Patent Application No. 10-2005-0034914, filed on Apr. 27, 2005, the subject matter of which is hereby incorporated by reference in its entirety.

2. Description of the Related Art

In many contemporary applications, flash memory is used as the main memory in a host device because of the excellent data integrity provided by its nonvolatile nature, as compared with the former use of DRAM. Flash memory is also routinely incorporated into host devices and related peripheral devices to provide bulk storage of data—thereby replacing existing hard disk and floppy disk data storage elements—because of its high data storage capacity and ease of integration.

The cell transistor used in conventional flash memory is formed on a substrate and is characterized by a stacked structure including a tunnel oxide layer, a floating gate, an inter-gate insulating layer, and a control gate. A programming operation (i.e., a data value storage operation) for a flash memory device having this gate structure is accomplished by the application of a positive voltage to the control gate, which is coupled to the floating gate. With application of this positive voltage, electrons migrate from the substrate to the floating gate through the tunnel oxide layer. This electron migration phenomenon may be the result of the so-called Fowler-Nordheim tunneling effect or hot carrier injection.

Both of these effects are related to the generation of a sufficiently high electric field. In order to develop this high electric field relative to the tunnel oxide layer at a low control gate input voltage, a high coupling ratio must exist between the control gate and the floating gate. The ratio between the voltage induced at the floating gate and the voltage applied to the control gate is termed a “coupling ratio.” The coupling ratio may also be described as a ratio between the capacitance of the inter-gate insulating layer and the sum of the capacitances of the tunnel oxide layer and the inter-gate insulating layer.

Figure (FIG.) 1 is a sectional view schematically illustrating the cell transistor of a conventional flash memory.

Referring to FIG. 1, isolation regions 2 are formed in a substrate 1 with a tunnel oxide layer 3 interposed between them. A floating gate 4 is formed on substrate 1 between isolation regions 2. Further, a control gate 7 is formed on floating gate 4 with an inter-gate insulating layer 6 interposed between them.

In the flash memory device having this conventional structure, the surface area of inter-gate insulating layer 6, as formed on the upper surface and sidewalls of floating gate 4, influences a coupling ratio. However, increasing the surface area of the inter-gate insulating layer 6 in this conventional cell area structure also increases the size of floating gate 4.

In order to minimize the coupling capacitance between adjacent flash memory cells, a structure such as the one shown in FIG. 2 has been conventionally proposed. This structure is characterized by the formation of a recess in each isolation region 2 separating the adjacent cells. (Inter-gate insulating layer 6 and control gate 7 are not shown in FIG. 2). Reference number 2′ is used to indicate the recessed isolation regions.

However, if the design rule for the constituent flash memory device is 60 nm or lower—which is common in contemporary and emerging flash devices—the distance between neighboring cells may be 40 nm or less. This remarkably small (and shrinking) separation distance causes the inter-cell coupling capacitance to increase accordingly. In an attempt to reduce or minimize the inter-cell coupling capacitance, the height of floating gate 4 has been reduced in some conventional designs. However, reducing the height of floating gate 4 also reduces the coupling ratio, and at some point the reduced coupling ration may cause the flash memory device to fail. Thus, the foregoing conventional remedies find increasingly limited application in the design and fabrication of flash memory having smaller and smaller design rules.

In order to overcome the foregoing limitations which often operate at cross purposes in relation to proposed remedies, a U-shape floating gate structure 5, such as that shown in FIG. 3, has been proposed. This structure has the advantage of an increased capacitive surface area formed between floating gate 5 and an inter-gate insulating layer (not shown). For example, if one calculates comparative capacitance areas for the floating gate structure 4 of FIG. 2 and the floating gate structure 5 of FIG. 3 assuming a design rule of 58 nm, the respective areas are 9296 nm² and 14336 nm². As this exemplary calculation suggests, the area of the U-shape floating gate 5 may be 40% greater than the floating gate 4. Thus, the coupling ratio may significantly increase, and a program voltage (V_{pgm}) may similarly be reduced.

In order to form the U-shaped floating gate structures 5 in a flash memory device, node separation is accomplished with a process that makes use of a polishing sacrificial layer (e.g., an oxide layer). In many ways this process is similar to conventionally-known processes used to fabricate cylindrical-shaped capacitor structures. In this process, the recessing of the floating gate and the isolation layer begins in a state in which the polishing sacrificial layer is disposed within the floating gate. Thus, the polishing sacrificial layer within the floating gate is etched during the recessing of the isolation layer so that the floating gate is exposed. In this manner, the floating gate may be recessed. Assuming a case where the floating gate is initially formed with a thickness of about 100 Å, the floating gate may be recessed to a thickness of about 70 Å during this process. Thus, it is difficult to realize the formation of a U-shape floating gate structure having a uniform thickness without layer loss and the resulting failures. Further, if portions of the polishing sacrificial layer remain after this process, a diluted HF solution must often be used to remove the residual portions. Unfortunately, this cleaning process may undesirably etch or recess isolation regions formed in a peripheral circuit region of the flash memory device.

### SUMMARY OF THE INVENTION

Embodiments of the invention provide a method of fabricating flash memory having a U-shape floating gate structure with a uniform thickness. This structure provides a high coupling ratio and avoids one or more the problems associated with the conventional devices. Additionally, embodiments of the invention provide a method of fabricating a flash memory during which isolation regions in a cell region of a substrate are effectively recessed, but associated isolation regions in a peripheral circuit region of the substrate are not similarly recessed.

### BRIEF DESCRIPTION OF THE DRAWINGS

The above and other features and advantages of the present invention will become more apparent upon consideration of several exemplary embodiments thereof with reference to the attached drawings in which:

FIG. 1 is a sectional view schematically illustrating a cell transistor of a conventional flash memory;

FIG. 2 is a sectional view illustrating the structure of a recessed isolation layer in FIG. 1;

FIG. 3 is a sectional view illustrating the structure of a U-shape floating gate in FIG. 2;

FIGS. 4 through 12 are sectional views illustrating a method of fabricating a flash memory according to an embodiment of the present invention in accordance with processing sequences;

FIGS. 13 through 18 are sectional views illustrating a method of fabricating a flash memory according to another embodiment of the present invention in accordance with processing sequences;

FIG. 19 illustrates etch amounts of an episilicon germanium layer in accordance with time by a silicon germanium etchant according to the present invention; and

FIG. 20 illustrates etch amounts of various layers in accordance with time by a silicon germanium etchant according to the present invention.

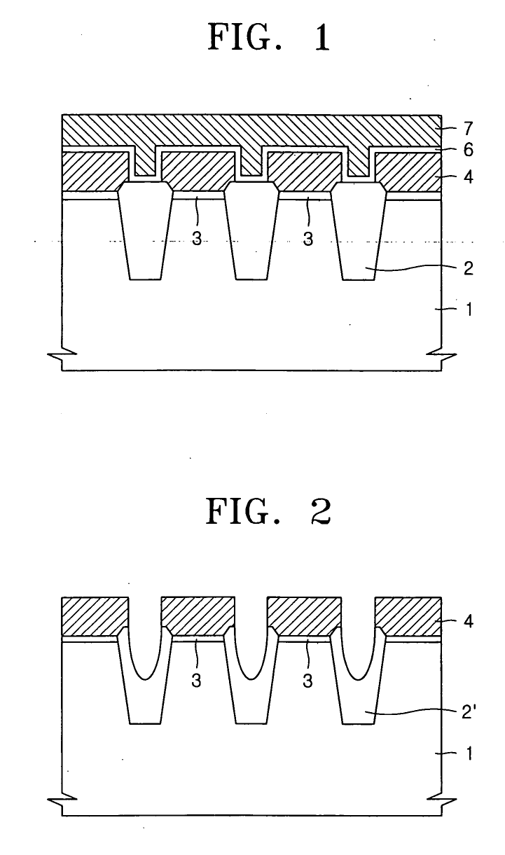

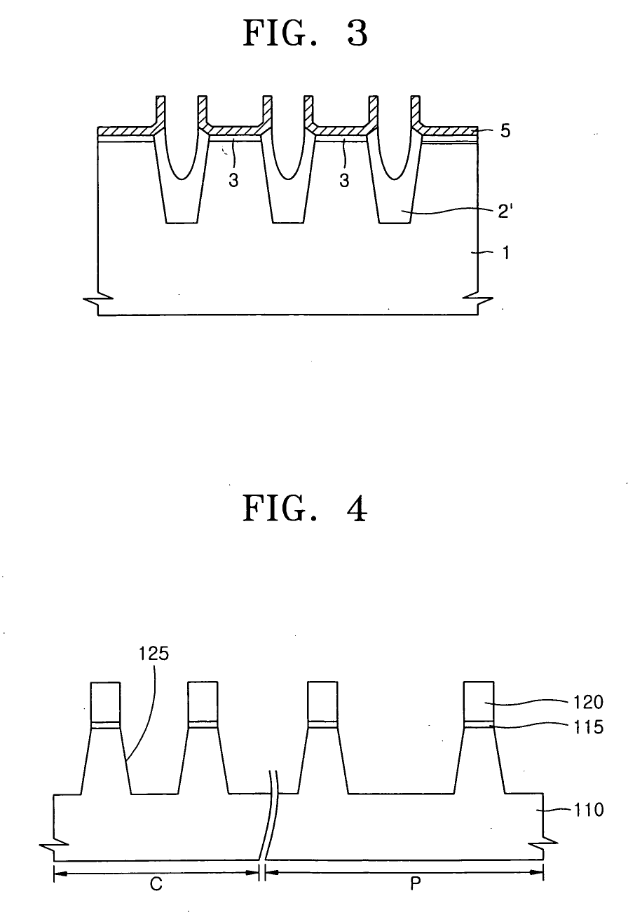

### DESCRIPTION OF EXEMPLARY EMBODIMENTS

The present invention will now be described with reference to the accompanying drawings in the context of several embodiments. The invention may, however, be embodied in many different forms and should not be construed as being limited to only the embodiments set forth herein. Rather, these embodiments are provided as teaching examples. Throughout this description, like numbers refer to like or similar elements.

FIGS. 4 through 12 are sectional views illustrating an exemplary method of fabricating a flash memory in accordance with one embodiment of the invention.

Referring to FIG. 4, a semiconductor substrate 110, for example a single crystal silicon substrate, is prepared and comprises of a cell region C and a peripheral circuit region P. Then, a pad oxide layer 115 and a pad nitride layer 120 are deposited on substrate 110 and patterned. Then, substrate 110 is etched using the patterned pad oxide layer 115 and pad nitride layer 120, thereby forming trenches 125 in substrate 110.

Before or after forming pad oxide layer 115, an ion implantation process may be performed on substrate 110 to form an ion layer adapted to define the impurity concentration of a well and to control a threshold voltage. Pad oxide layer 115 is formed to suppress crystal defects on the upper surface of substrate 110, or for surface treatment. Pad oxide layer 115 may be formed using a dry oxygen-based oxidation process or wet H₂O-based oxidation process at a temperature ranging between about 700° C. to 950° C. Pad oxide layer 115 may be formed to a thickness ranging from between about 50 Å to 250 Å using one of several types of conventionally available furnaces or processing chambers.

Pad nitride layer 120 may be deposited using, for example, a low pressure chemical vapor deposition (CVD) method that reacts SiH₄ and NH₃ at a temperature ranging from about 500° C. to 850° C. Pad nitride layer 120 may be formed to a thickness as high as the anticipated upper surface of the completed structure and on both sides of an isolation layer. In one embodiment, this thickness may range from about 500 Å to 3000 Å.

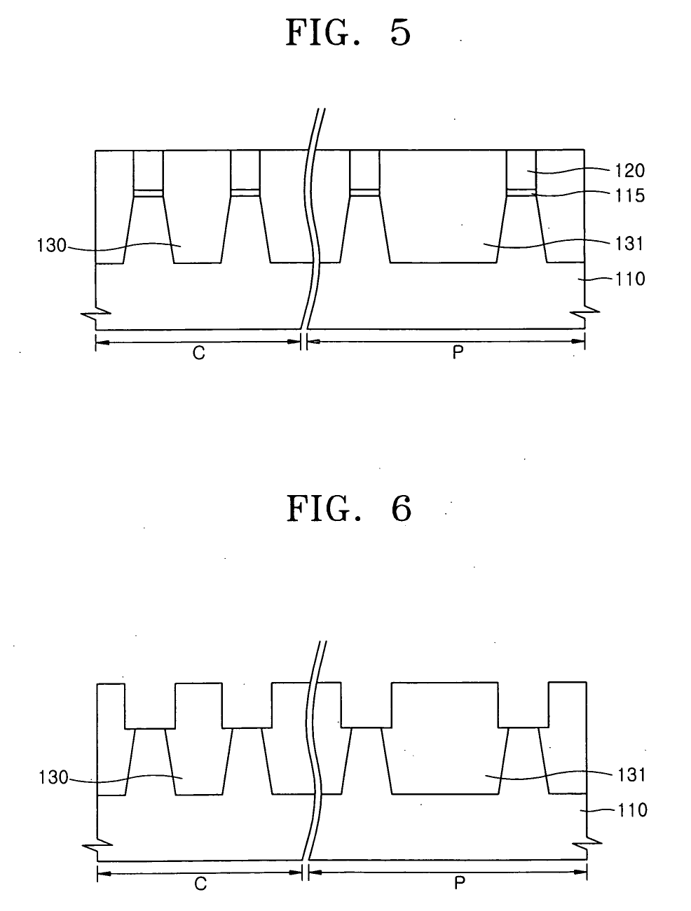

As illustrated in FIG. 5, an insulating layer is deposited to fill trenches 125. The insulating layer is then planarized to form isolation layers 130 and 131. By forming a thermal oxide layer on the inner walls and the bottom surfaces of trenches 125 before in-filling with the insulating layer, defects potentially caused during the trench etching process may be cured. Alternatively, a liner oxide layer or a liner nitride layer may be formed on the inner walls and bottom surfaces of trenches 125 in order to enhance the adhesiveness of the in-filling insulating layer, and thereby inhibit generation of a leakage current as well as the so-called moat phenomenon.

The insulating layer in-filling trenches 125 may be formed from a high density plasma (HDP) oxide layer, a middle temperature oxide (MTO), such as plasma enhanced-tetraethylorthosilicate (PE-TEOS), an undoped silicate glass (USG) oxide layer, or a composite layer formed from two or more of these materials or their like. Following its formation, the density of the insulating layer is enhanced using a thermal treatment process conducted at a temperature of about 800° C. to 1100° C., for example, in an the atmosphere of N₂, O₂, H₂O, or the like to remove moisture from the insulating layer and hardened it against potential damage from subsequently applied etching processes. As a result, the structural density of the insulating layer (e.g., one formed from a MTO) may be made equal to that of a thermal oxide layer. However, such densification processes may be optionally or selectively employed in view of the material actually used to form the insulating layer. A chemical mechanical polishing (CMP) process or an etch-back process using pad nitride layer 120 as a planarizing stop point may be used to planarize the insulating layer in-filling trenches 125. For example, one CMP process adapted to this application uses a slurry including a ceria (CeO₂) group of abrasive particles.

Referring to FIG. 6, pad nitride layer 120 and pad oxide layer 115 are removed to expose the upper surface and both side surfaces of isolation layers 130 and 131 which protruded from the surface of substrate 110. Pad nitride layer 120 may be removed, for example, using phosphoric acid (H₃PO₄) stripping. Pad oxide layer 115 may be removed, for example, using a wet etch-back process. In one embodiment, a wet etchant well adapted to the removal of pad oxide layer 115 comprises SC-1, which may be formed from a diluted HF solution, NH₄OH, H₂O₂, and H₂O, and/or a buffered oxide etchant (BOE) (e.g., a solution of HF and NH₄F mixed at a ratio of 100:1 or 300:1). During application of processes adapted to remove pad nitride layer 120 and pad oxide layer 115, the upper and side surfaces of isolation layers 130 and 131 may be etched to selectively decrease the overall widths of the exposed portions of these elements.

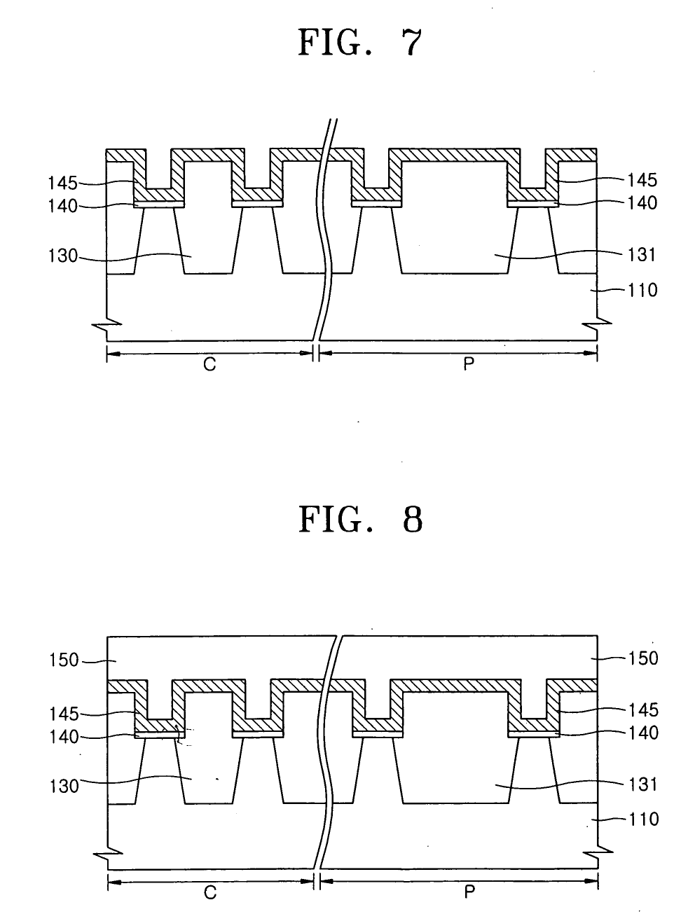

Referring to FIG. 7, a tunnel oxide layer 140 is formed on the exposed portion of substrate 110 between adjacent isolation layers 130 and 131. Tunnel oxide layer 140 may be formed to a thickness ranging from about 85 Å to 11 Å, or as thin as necessary to allow effective electron tunneling. For example, tunnel oxide layer 140 may be formed using wet oxidation process conducted at a temperature ranging from about 750° C. to 800° C., and an annealing process performed in a nitrogen atmosphere at a temperature ranging from about 900° C. to 910° C. for 20 through 30 minutes. This combination of processes tends to minimize the defect density at the interface between tunnel oxide layer 140 and substrate 110.

Following formation of tunnel oxide layer 140, a conductive layer 145 is formed from a doped polysilicon layer, for example, having a thickness sufficiently thin (e.g., 100 Å) so as not to completely in-fill the gap portions between adjacent ones of isolation layers 130 and 131. The doped polysilicon layer may be formed, for example, by depositing undoped silicon using a low pressure CVD (LPCVD) at a temperature ranging from 500° C. to 700° C. After the deposition of this undoped layer, selected impurities, such as arsenic (As) or phosphorus (P), may be ion implanted into the polysilicon layer. Alternatively, a doped polysilicon layer may be formed by introducing the impurities using in an in-situ manner during the deposition process. A doping density for the polysilicon layer may range, for example, to 1E21 or higher.

Referring to FIG. 8, a sacrificial layer 150 (e.g., a silicon germanium layer) well adapted to the subsequently performed polishing process is formed on conductive layer 145. In one embodiment, sacrificial layer 150 is formed to a thickness (e.g., 300 Å to 5000 Å) sufficient to completely in-fill the residual gaps formed between adjacent ones of isolation layers 130 and 131. Sacrificial layer 150 may be formed by depositing silicon germanium on conductive layer 145, or by epitaxially growing silicon germanium on conductive layer 145.

In a case where conductive layer 145 is formed from a doped polysilicon layer, a polysilicon germanium layer may be formed by the deposition of silicon germanium. The silane group of gases such as SiH₄, Si₂H₆, SiH₂Cl₂ or the like, and a gas such as GeH₄, GeF₄ or the like may be used as a source gases for the deposition of the silicon germanium. The amount of germanium in a sacrificial layer 150 formed from a silicon germanium layer may be controlled by the flow ratio of a germanium source gas into the formation process in view of the desired materials characteristics of layer being formed. In order to control the flow ratio precisely, it is possible to dilute GeH₄ or the like as Ge source with hydrogen or nitrogen and supply. As the amount of germanium in the silicon germanium layer is high, the silicon germanium layer may be etched faster than the polysilicon layer. Because of this result, it is preferable in some embodiments of the invention to increase the amount of germanium to as high as reasonably possible in order to develop an etch selectively for sacrificial layer 150 relative to conductive layer 145. In one embodiment, a desired etch rate cannot be achieved for an amount of germanium of 10% or less by weight based on a total weight of the silicon germanium layer. Thus, the amount of germanium in a sacrificial layer 150 formed from a silicon germanium layer may range from about 10% to 100%.

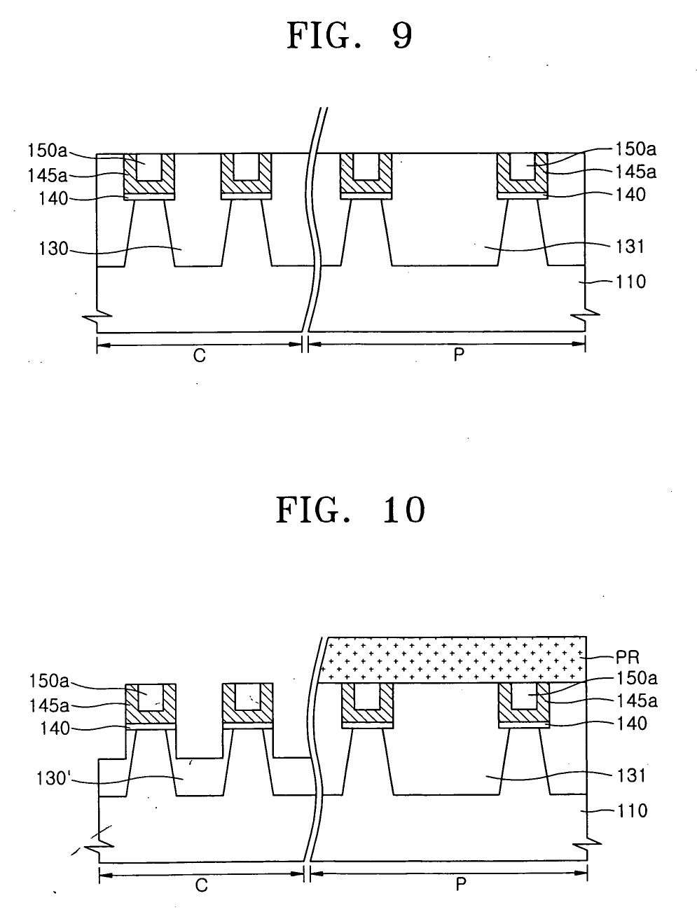

Referring to FIG. 9, sacrificial layer 150 and conductive layer 145 are removed except for the portions in-filling the gaps between adjacent one of isolation layers 130 and 131, to thereby form a U-shape floating gate 145a which are self-aligned between adjacent ones of isolation layers 130 and 131. This removal process also leaves a residual portion of sacrificial layer 150 (i.e., a sacrificial layer pattern 150a) within each floating gate 145a.

Sacrificial layer 150 and conductive layer 145 may be removed, for example, using a CMP. In one embodiment, sacrificial layer 150 is formed from a silicon germanium layer and conductive layer 145 is formed from a doped polysilicon layer. The silicon germanium and polysilicon layers have similar material properties. Thus, sacrificial layer 150 and conductive layer 145 can be effectively removed using a CMP without significant selectivity between these two layer types. In one embodiment each floating gate 145a is formed to a height of about 600 Å.

Referring to FIG. 10, a photoresist pattern (PR) exposing cell region C is formed on a resultant structure including sacrificial layer pattern 150a. By recessing isolation layers 130 in cell region C using sacrificial layer pattern 150a, floating gate 145a, and tunnel oxide layer 140 as a mask, the outer sidewalls of floating gate 145a may be exposed. The recessing of isolation layers 130 may be accomplished using a dry etch process or a wet etch-back process. A reference number 130′ indicates the recessed isolation layer 130. In one embodiment, a recess depth of about 850 Å may be formed, as measured from the upper surface of floating gate 145a.

In one embodiment, sacrificial layer pattern 150a is formed from a silicon germanium layer, and isolation layer 130 is formed from a MTO, such as USG. Since a selectivity of silicon germanium with respect to this type of oxide is 10 or higher, sacrificial layer pattern 150a is not etched away, but remains throughout the process of recessing isolation layer 130 and in this manner protects substantial portions (e.g., the inner sidewalls and inner bottom surface) of floating gate 145a. Thus, embodiments of the invention provide a U-shaped floating gate structure 145a that is not significantly etched (or non-uniformly thinned) during the process of recessing isolation layer 130.

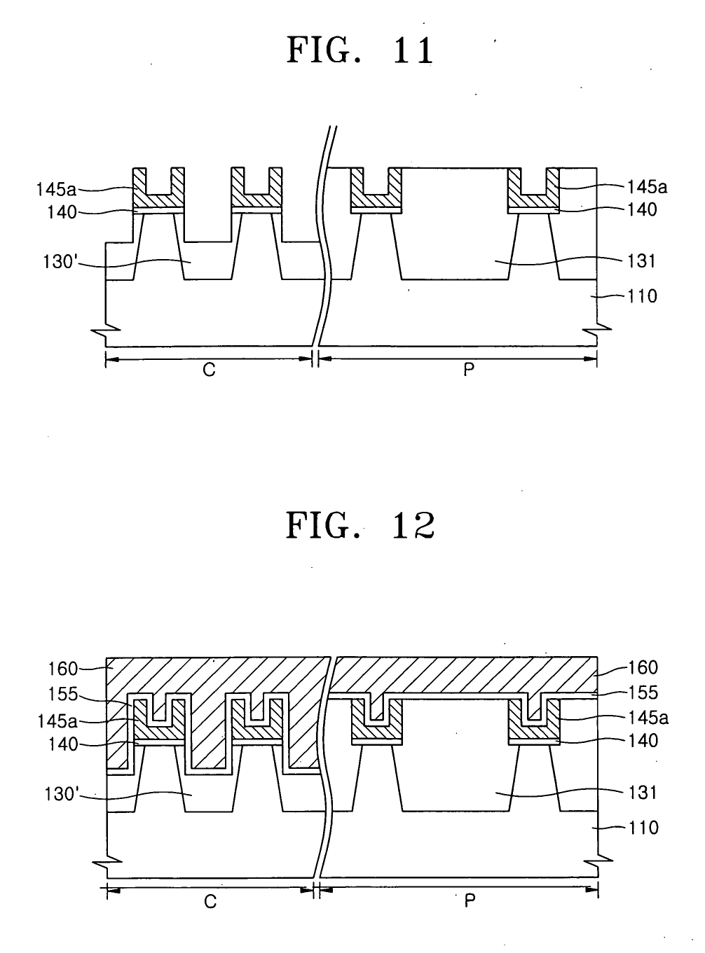

Referring to FIG. 11, the photoresist pattern PR is removed using, for example, an ashing and stripping process. Additionally, sacrificial layer pattern 150a is selectively removed with respect to floating gate 145a to thereby expose the entire upper surface of floating gate 145a. In one embodiment, an etchant having a selectivity of 30 or higher for sacrificial layer pattern 150a with respect to floating gate 145a is used in order to selectively remove sacrificial layer pattern 150a. In order to remove sacrificial layer pattern 150a formed from silicon germanium with respect to floating gate 145a formed from polysilicon, an ammoniac solution may be used that comprises ammonium hydroxide (NH₄OH) and hydrogen peroxide (H₂O₂); a polyetchant solution having four components of HF/HNO₃/CH₃COOH/deionized water (DIW); a solution having three components of HF/HNO₃/DIW; solution having three components of HF/H₂O₂/DIW; mixing solution of HNO₃, HF, and DIW; and mixing solution of HF, CH₃COOH, and H₂O₂.

Alternatively, one embodiment of the invention proposes use of a silicon germanium etchant containing peroxyacetic acid in order to achieve a relative selectivity of 30 or higher. One acceptable etchant of this type comprises peroxyacetic acid, fluoride, and solvent. The amount of peroxyacetic acid in such an etchant may range from between 1 to 50% by weight based on the total weight of the etchant. In one embodiment, the fluoride is fluoric acid, and the solvent is acetic acid. In such an embodiment, the amount of peroxyacetic acid ranges from 1 and 50% by weight based on the total weight of the etchant, the amount of fluoric acid ranges from about of 0.1 to 30% by weight, and the amount of acetic acid ranges from about 10 to 50% by weight. Deionized water may also be added to the etchant solution in an amount that ranges from 10 to 40% by weight based on the total weight of the etchant. In addition, a surfactant or similar substance may be added to the etchant solution, as desired.

As the peroxyacetic acid has an excellent oxidative property, the silicon germanium can be removed with a high etch selectivity of 30:1 or more without causing damage to the polysilicon layer in the foregoing example. If an etchant including peroxyacetic acid is used, a sacrificial layer pattern 150a formed from silicon germanium may be selectively removed with respect to a polysilicon floating gate 145a without recessing (or thinning) floating gate 145a. Thus, floating gate 145a may be formed with a uniform thickness.

Further, as described above, since the selectivity of silicon germanium with respect to the oxide is 10 or more, isolation layer 131 of the peripheral circuit region P is not recessed while removing sacrificial layer pattern 150a.

Referring to FIG. 12, after an inter-gate insulating layer 155 is formed on the exposed floating gate 145a, a control gate 160 is formed on inter-gate insulating layer 155. Inter-gate insulating layer 155 may be formed from an oxide/nitride/oxide (ONO) layer. Alternatively, inter-gate insulating layer 155 may be formed from a dielectric material having a high dielectric constant. After inter-gate insulating layer 155 is formed, an annealing process may be performed to remove trapping electrons and to improve the layer's material properties.

Control gate 160 may be formed from polysilicon, silicide, polycide, and/or a metal layer. A constituent silicide may be formed from tungsten silicide, cobalt silicide, and/or titanium silicide, for example. A cobalt silicide and titanium silicide may be formed by first depositing polysilicon, then depositing cobalt or titanium, and thereafter performing one or more rapid thermal annealing (RTA) process(es).

In a case where cobalt silicide is used, a first RTA process may be performed at a temperature of between 400° C. to 500° C. in a nitrogen atmosphere for about 50 seconds to cause reaction between the polysilicon and cobalt in order to form a CoSi layer. Then, a second RTA process may be performed on the resultant structure at a temperature of between 800° C. to 900° C. in a nitrogen atmosphere for about 30 seconds in order to form a low resistance layer of CoSi₂.

In the case where nickel silicide is used, a first annealing process may be performed at low temperature to form a NiSi layer. A tungsten silicide may thereafter be directly deposited using CVD. The resulting polycide includes a stacked structure of polysilicon and silicide.

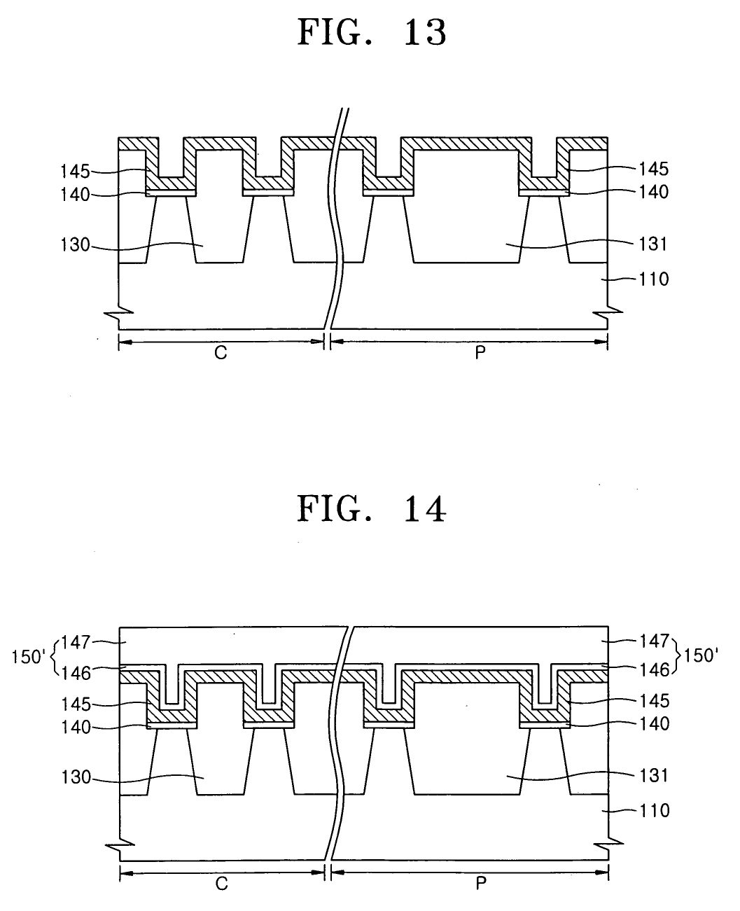

FIGS. 13 through 18 are sectional views illustrating another embodiment of the invention adapted to the fabrication of a flash memory. Certain descriptive portions of this alternate embodiment are similar to analogous portions of the foregoing description and will be omitted for the sake of brevity.

Referring to FIG. 13, the exemplary process steps described with respect to FIGS. 4 through 6 are assumed to have been performed, thereby forming isolation layers 130 and 131 on substrate 110 including a cell region C and a peripheral circuit region P, wherein an upper surface and side portions of isolation layers 130 and 131 protruded from the surface of substrate 110. A tunnel oxide layer 140 is then formed on an exposed portion of substrate 110 between adjacent ones of isolation layers 130 and 131 (e.g., in a formed gap). Then, a conductive layer 145, preferably formed in one embodiment from a doped polysilicon layer is formed to a thickness that does not completely fill the gap between adjacent ones of isolation layers 130 and 131.

Referring to FIG. 14, a silicon germanium layer 146 is formed on conductive layer 145 to a thickness (e.g., between about 10 Å to 300 Å) on conductive layer 145 that does not completely fill the gap between adjacent ones of isolation layers 130 and 131. Silicon germanium layer 146 may be formed by depositing silicon germanium on conductive layer 145 or epitaxially growing the silicon germanium layer.

An oxide layer 147 is then formed on silicon germanium layer 146 to completely fill the gap between adjacent ones of isolation layers 130 and 131. Oxide layer 147 may be formed from a phosphorus silicate glass (PSG), a boron phosphorus silicate glass (BPSG), spin on glass (SOG), or the like.

A sacrificial layer 150′ well adapted to the subsequently performed polishing process may then be formed from silicon germanium layer 146 and oxide layer 147.

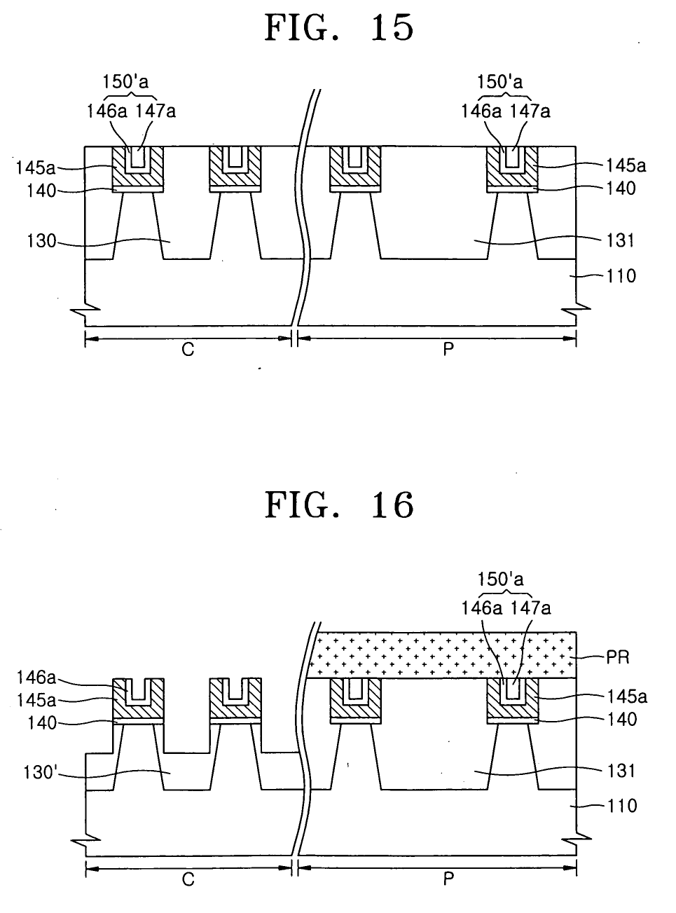

Referring to FIG. 15, sacrificial layer 150′ and conductive layer 145 on isolation layers 130 and 131 are removed to form U-shape floating gate 145a self-aligned in the gap between adjacent ones of isolation layers 130 and 131. Concurrently, a residual portion of sacrificial layer 150′ (e.g., sacrificial layer pattern 150′a) remains within floating gate 145a.

Referring to FIG. 16, a photoresist pattern PR exposing cell region C is formed on the resultant structure including sacrificial layer pattern 150′a. The isolation layers 130 in cell region C are then recessed using sacrificial layer pattern 150′a to protect floating gate 145a, and using sacrificial layer pattern 150′a, floating gate 145a, and tunnel oxide layer 140 as a mask to thereby expose the outer sidewalls of floating gate 145a. The reference number, 130′ indicates a recessed isolation layer. At this time, an oxide layer pattern 147a (e.g., part of sacrificial layer pattern 150′a) is removed while recessing isolation layers 130. However, floating gate 145a is not recessed due to the presence of silicon germanium layer pattern 146a.

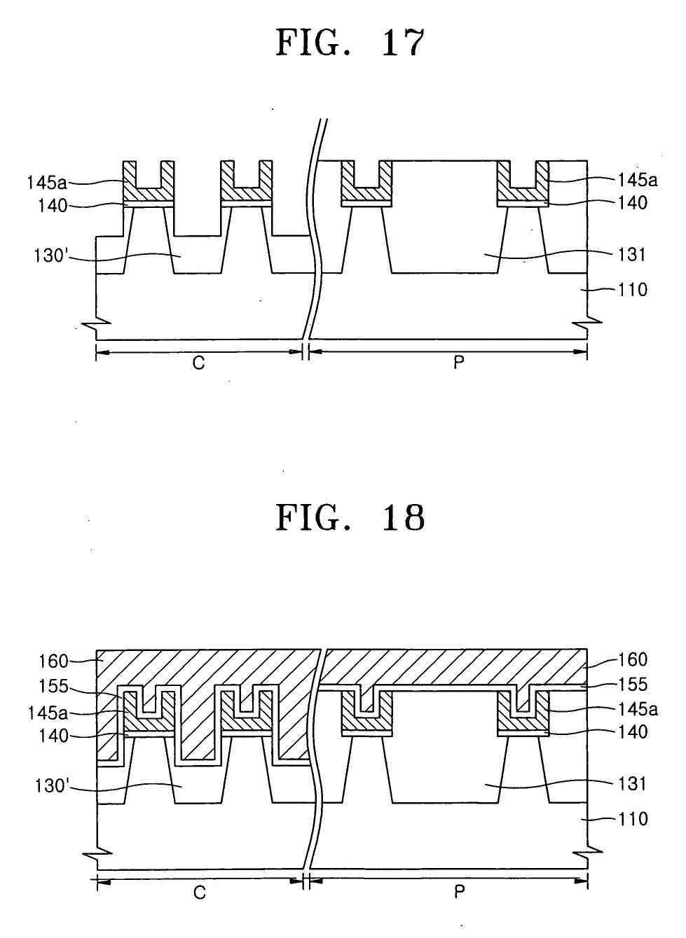

Referring to FIG. 17, after the photoresist pattern PR is removed, silicon germanium layer pattern 146a is removed to thereby expose the upper surface of floating gate 145a. Analogous to the discussion above, an etchant having a selectivity of 30 or more for sacrificial layer pattern 150′a, (as now formed from only silicon germanium layer pattern 146a, since oxide layer pattern 147a was removed above) with respect to floating gate 145a may be used. As described above, an etchant comprising peroxyacetic acid, fluoric acid, and acetic acid may be preferable in some embodiments. As above, the amount of the peroxyacetic acid may range from 1 to 50% by weight based on the total weight of the etchant, the amount of fluoric acid may range from 0.1 to 30% by weight, and the amount of acetic acid may range from 10 to 50% by weight.

Referring to FIG. 18, after an inter-gate insulating layer 155 is formed on the exposed floating gate 145a, a control gate 160 is formed on inter-gate insulating layer 155.

In the illustrated examples, the process of removing a sacrificial layer pattern 150a formed from silicon germanium, or removing the silicon germanium layer pattern 146a of sacrificial layer pattern 150′a with respect to the floating gate 145a with a selectivity is an important feature. For this reason, a silicon germanium etchant comprising peroxyacetic acid has been found to be useful in some embodiments of the invention. Consider, for example an experimental example further illustrating the usefulness of this type of etchant within the context of embodiments of the invention.

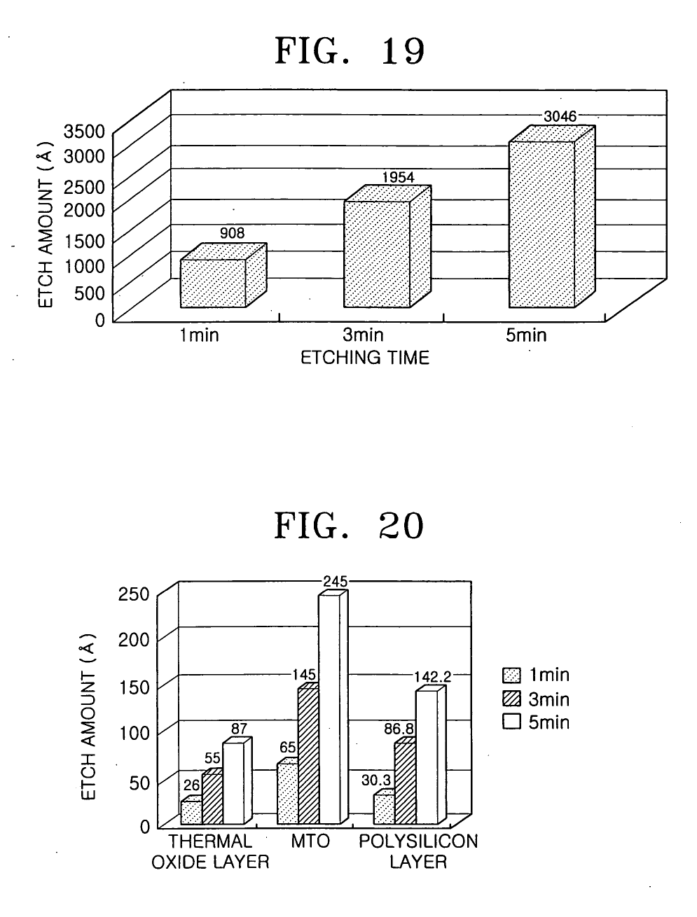

Referring to FIG. 19, exemplary etch quantities for epitaxial silicon germanium using a silicon germanium etchant as described above are illustrated. The amount of germanium in the tested silicon germanium layer was 20% by weight based on a total weight of the silicon germanium layer. The etchant was prepared by mixing peroxyacetic acid (30% by weight), fluoric acid (49% by weight), acetic acid, and deionized water at a volume ratio of 1.8:30:30:30, and adding nonionic surfactant (0.1% by weight). An etch quantity for the silicon germanium layer after one minute of etching was found to be 908 Å. An etch quantity for the silicon germanium layer after three minutes of etching was found to be 1954 Å. Finally, an etch quantity for the silicon germanium layer after five minutes of etching was found to be 3046 Å.

Since the etch rate increases with the amount of germanium, greater etch qualities per unit time may be obtained by adjusting the germanium content. If the silicon germanium layer is composed of polysilicon germanium rather than being formed epitaxially, the etchant may penetrate along crystal boundaries more efficiently and thus, an increased etch rate may be obtained.

FIG. 20 illustrates respective etch quantities for various thin films in relation to the above described etchant for several time periods. For example, an etch quantity after one minute of etching for a thermal oxide layer was found to be 26 Å, for MTO was found to be 65 Å, and for polysilicon layer was found to be 30.3 Å.

As shown from FIGS. 19 and 20, a selectivity for silicon germanium with respect to a polysilicon layer is about 30 for a case wherein amount of germanium was about 20% by weight. If the germanium content increases, the selectivity will increase. If the silicon germanium layer is composed of polysilicon germanium not an epitaxial layer, the selectivity is increased to 30 or higher. A selectivity for silicon germanium with respect to a thermal oxide layer and MTO was found to be about 24 to 30 or higher. Thus, when removing the sacrificial layer pattern of a silicon germanium layer or the silicon germanium layer pattern of the sacrificial layer pattern with respect to the floating gate, it was found that the isolation layer of an oxide layer in the peripheral circuit region was immaterially recessed.

As described above, and in accordance with embodiments of the invention, by forming the upper surface of the floating gate in a U shape, the surface area of the associated inter-gate insulating layer may be increased without increasing the cell size so as to increase the corresponding coupling ratio. Therefore, the efficiency of data storage and erase operations for a flash memory cell incorporating the U-shaped floating gate may be improved without adversely affecting the degree of integration.

When the U-shape floating gate is formed, use of a silicon germanium layer as a sacrificial layer is proposed. This type of layer supports the floating gate during node separation using a conventional CMP, or the like, and protects the floating gate during a subsequently applied process adapted to recess the isolation layer. Further, the sacrificial layer may be selectively removed from the floating gate using an etchant including peroxyacetic acid.

Therefore, according to embodiments of the invention, the floating gate may be protected from damage during a process adapted to recess the isolation layer, and the floating gate may be further protected from damage during a process adapted to remove the sacrificial layer or residual portions thereof. Therefore, the floating gate may be maintained with a uniform thickness and deterioration of the electrical characteristics of the flash memory cell due to damage of the floating gate may be avoided. Further, since in some embodiments the etchant including peroxyacetic acid provides a selectivity of silicon germanium with respect to an oxide, the isolation layer in the peripheral circuit region is not recessed when the sacrificial layer is selectively removed from the floating gate.

While the present invention has been particularly shown and described with reference to exemplary embodiments thereof, it will be understood by those of ordinary skill in the art that various changes in form and details may be made therein without departing from the scope of the invention as defined by the following claims.

What is claimed is:

1. A method of fabricating a flash memory comprising:
forming isolation layers on a substrate, wherein upper surface portions of adjacent isolation layers are separated by a gap;
forming a tunnel oxide layer in the gap on the substrate;
forming a conductive layer on the tunnel oxide layer to a thickness that does not completely in-fill the gap;
forming a sacrificial layer on the conductive layer to completely in-fill the gap;
selectively removing the sacrificial layer and the conductive layer to form a U-shape floating gate from the conductive layer in the gap and to concurrently form a sacrificial layer pattern from the sacrificial layer within an inner portion of the floating gate;
selectively recessing at least one of the isolation layers to expose a sidewall of the floating gate; and
removing the sacrificial layer pattern from the floating gate to expose an upper surface of the floating gate.

2. The method according to claim 1, wherein a selectivity for the sacrificial layer pattern with respect to the floating gate is 30 or higher in relation to a process adapted to remove the sacrificial layer pattern.

3. The method according to claim 1, wherein the conductive layer is formed from a doped polysilicon layer.

4. The method according to claim 3, wherein the sacrificial layer is formed from a silicon germanium layer.

5. The method according to claim 4, wherein the silicon germanium layer is formed to a thickness sufficient to completely in-fill the gap.

6. The method according to claim 3, wherein the sacrificial layer is formed from a double layer comprising a silicon germanium layer first formed to a thickness that does not in-fill the gap, and an oxide layer formed to a thickness sufficient to completely in-fill the gap.

7. The method according to claim 6, wherein the oxide layer is removed during the selective recessing of the isolation layers.

8. The method according to claim 4, wherein the silicon germanium layer is formed by depositing silicon germanium on the conductive layer.

9. The method according to claim 4, wherein the silicon germanium layer is formed by epitaxially growing silicon germanium on the conductive layer.

10. The method according to claim 4, wherein the silicon germanium layer comprises germanium of about 10% to 100% by weight, based on a total weight of the silicon germanium layer.

11. The method according to claim 4, wherein removing the sacrificial layer pattern comprises:
applying an etchant comprising peroxyacetic acid, fluoride and a solvent.

12. The method according to claim 11, wherein the etchant comprises peroxyacetic acid in a range of from 1% to 50% by weight based on a total weight of the etchant.

13. The method according to claim 11, wherein the fluoride comprises fluoric acid, and the solvent comprises acetic acid.

14. The method according to claim 13, wherein the etchant comprises by weight; peroxyacetic acid in a range of from 1% to 50%, fluoric acid in a range of from 0.1% to 30%, and acetic acid in a range of from 10% to 50% by weight.

15. The method according to claim 13, wherein the etchant further comprises deionized water.

16. The method according to claim 15, wherein the etchant comprises deionized water in a range of from 10% to 40% by weight.

17. A method of fabricating a flash memory comprising:
forming isolation layers on a substrate, wherein the substrate comprises a cell region and a peripheral circuit region, and wherein upper portions of adjacent isolation layers are separated by a gap;
forming a tunnel oxide layer in the gap on the substrate;
forming a conductive layer from a doped polysilicon layer on the tunnel oxide layer to a thickness that does not completely in-fill the gap;
forming a sacrificial layer from silicon germanium on the conductive layer;
selectively removing the sacrificial layer and the conductive layer to form a U-shape floating gate from the conductive layer in the gap, and to concurrently form a sacrificial layer pattern from the sacrificial layer within an inner portion of the floating gate;
forming a photoresist pattern on the substrate to expose the cell region;
recessing isolation layers in the cell region to expose both sidewalls of the floating gate;
removing the photoresist pattern; and
removing the sacrificial layer pattern from the floating gate to expose an upper surface of the floating gate.

18. The method according to claim 17, wherein the silicon germanium layer is formed to a thickness that completely in-fills the gap.

19. The method according to claim 17, wherein the sacrificial layer comprises:
a silicon germanium layer is formed to a thickness that does not completely in-fill the gap; and, an oxide layer formed on the silicon germanium layer to a thickness sufficient to completely in-fill the gap.

20. The method according to claim 19, wherein the oxide layer is removed during the recessing of the isolation layers in the cell region.

21. The method according to claim 17, wherein a selectivity of the sacrificial layer pattern with respect to the floating gate is 30 or higher with respect to a process adapted to selectively remove the sacrificial layer pattern.

22. The method according to claim 17, wherein the silicon germanium layer comprises germanium in a range of from 10% to 100% by weight based on a total weight of the silicon germanium layer.

23. The method according to claim 17, wherein removing the sacrificial layer pattern comprises:
applying an etchant comprising peroxyacetic acid, fluoride and a solvent.

24. The method according to claim 23, wherein the etchant comprises peroxyacetic acid in a range of from 1% to 50% by weight based on a total weight of the etchant.

25. The method according to claim 23, wherein the fluoride comprises fluoric acid, and the solvent comprises acetic acid.

26. The method according to claim 25 wherein the etchant comprises by weight; peroxyacetic acid in a range of from 1% to 50%, fluoric acid in a range of from 0.1% to 30%, and acetic acid in a range of from 10% to 50% by weight.

27. The method according to claim 25, wherein the etchant further comprises deionized water.

28. The method according to claim 27, wherein the etchant comprises deionized water in a range of from 10% to 40% by weight.

29. The method according to claim 17, further comprising:
forming an inter-gate insulating layer on the exposed floating gate; and
forming a control gate on the inter-gate insulating layer.
